(19) United States
(12) Patent Application Publication
(10) Pub. No.: US 2026/0353557 A1
(43) Pub. Date: Nov. 5, 2026

(54) PRINTED CIRCUIT BOARD

(71) Applicant: SAMSUNG ELECTRO-MECHANICS CO., LTD., Suwon-si (KR)

(72) Inventors: Chan Hoon KO, Suwon-si (KR); Sang Hoon KIM, Suwon-si (KR); Ki Eun CHO, Suwon-si (KR); Ji Ho YOON, Suwon-si (KR); Young Il CHO, Suwon-si (KR); Min Jae SEONG, Suwon-si (KR)

(73) Assignee: SAMSUNG ELECTRO-MECHANICS CO., LTD., Suwon-si (KR)

(21) Appl. No.: 19/535,347

(22) Filed: Feb. 10, 2026

(30) Foreign Application Priority Data
Apr. 30, 2025 (KR) 10-2025-0057052
Sep. 15, 2025 (KR) 10-2025-0131854

(51) Int. Cl. H05K 1/11; H05K 1/181

(52) U.S. Cl. CPC H05K 1/113; H05K 1/181; H05K 2201/0367; H05K 2201/09527; H05K 2201/099

(57) ABSTRACT

A printed circuit board includes: an insulating layer; a first conductive pattern disposed on or in the insulating layer; a first conductive bump disposed on the first conductive pattern; and a solder resist layer disposed on the insulating layer, covering at least a portion of the first conductive pattern, covering a portion of the first conductive bump, and exposing another portion of the first conductive bump, wherein when a maximum thickness measured from at least a portion of an upper surface of the first conductive pattern to an upper surface of the solder resist layer is defined as t1, and a maximum thickness measured from the upper surface of the solder resist layer to an upper surface of the first conductive bump is defined as t2, a thickness ratio of t2 relative to t1 is in a range of 7:3 to 2:8.

### CROSS-REFERENCE TO RELATED APPLICATION(S)

This application claims benefit of priority to Korean Patent Application Nos. 10-2025-0057052 filed on Apr. 30, 2025, and 10-2025-0131854 filed on Sep. 15, 2025 in the Korean Intellectual Property Office, the disclosures of which are incorporated herein by reference in their entirety.

### TECHNICAL FIELD

The present disclosure relates to a printed circuit board.

Recent advancements in increased performance and integration of information devices have led to an increase in the number of input and output terminals on a single semiconductor chip, together with a higher interconnection density, thereby requiring a finer and more precise pattern in a connection structure between a semiconductor chip and a board. In particular, as interconnection technologies between semiconductor chips for high-speed interfaces have been developed, an interconnection pitch in boards has become extremely narrow, and a distance between pads has also decreased. In such an environment, when the semiconductor chip is mounted on a board, interference may occur between connection pads and adjacent interconnections due to alignment errors or slight deformations of the board, which may lead to a risk of electrical short circuits. Such a risk may increase as the pitch between interconnections and pads becomes narrower. To prevent such short circuits, a process of forming a solder resist, an insulating film, is required. However, it is difficult to precisely form the solder resist in a fine space between bumps to have an accurate position and thickness by a conventional method.

### SUMMARY

An aspect of the present disclosure is to provide a printed circuit board capable of preventing a risk of short circuits, having excellent solder wettability, and having a stable solder resist structure.

The present disclosure provides a conductive pattern in which an embedded or convex pattern structure is formed on an outermost portion of a board, a conductive bump is formed on the conductive pattern, a solder resist layer covering these components is formed, and a solder resist layer is then partially removed to expose a portion of the conductive bump, thereby allowing a ratio between a height of the exposed conductive bump and a thickness of the remaining solder resist layer to be within a specific range.

According to an aspect of the present disclosure, a printed circuit board may include: an insulating layer; a first conductive pattern embedded in an upper portion of the insulating layer and having an upper surface exposed from an upper surface of the insulating layer; a first conductive bump disposed on the first conductive pattern and connected to a first portion of the exposed upper surface of the first conductive pattern; and a solder resist layer disposed on the insulating layer, covering a second portion of the exposed upper surface of the first conductive pattern distinct from the first portion of the exposed upper surface of the first conductive pattern, covering a first portion of a side surface of the first conductive bump, and exposing a second portion of the side surface of the first conductive bump distinct from the first portion of the side surface of the first conductive bump, wherein when a maximum thickness measured from the second portion of the exposed upper surface of the first conductive pattern to an upper surface of the solder resist layer is defined as t1, and a maximum thickness measured from the upper surface of the solder resist layer to an upper surface of the first conductive bump is defined as t2, a thickness ratio of t2 to t1 is in a range of 7:3 to 2:8.

According to another aspect of the present disclosure, a printed circuit board may include: an insulating layer; a first conductive pattern disposed on an upper surface of the insulating layer and having a convex upper surface; a first conductive bump disposed on the first conductive pattern and connected to a first portion of the convex upper surface of the first conductive pattern; and a solder resist layer disposed on the insulating layer, covering a second portion of each of the convex upper surface and side surface of the first conductive pattern distinct from the first portion of the convex upper surface of the first conductive pattern, covering a first portion of a side surface of the first conductive bump, and exposing a second portion of the side surface of the first conductive bump distinct from the first portion of the side surface of the first conductive bump, wherein when a maximum thickness measured from the second portion of the convex upper surface of the first conductive pattern to an upper surface of the solder resist layer is defined as t1, and a maximum thickness measured from the upper surface of the solder resist layer to an upper surface of the first conductive bump is defined as t2, a thickness ratio of t2 to t1 is in a range of 7:3 to 2:8.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating a printed circuit board according to an example embodiment;

FIG. 4 is an enlarged cross-sectional view schematically illustrating an R region of the printed circuit board in FIG. 3;

FIG. 5 is an enlarged cross-sectional view schematically illustrating a modified example of the R region in FIG. 4;

FIG. 6 is an enlarged cross-sectional view schematically illustrating another modified example of the R region in FIG. 4;

FIG. 7 is a cross-sectional view schematically illustrating a printed circuit board according to another example embodiment;

FIG. 8 is an enlarged cross-sectional view schematically illustrating an S region of the printed circuit board in FIG. 7;

FIG. 9 is an enlarged cross-sectional view schematically illustrating a modified example of the S region in FIG. 8; and

FIG. 10 is an enlarged cross-sectional view schematically illustrating another modified example of the S region in FIG. 8.

### DETAILED DESCRIPTION

Hereinafter, the present disclosure is described with reference to the accompanying drawings. The shapes, sizes, and the like of elements in the drawings may be exaggerated or reduced for clearer description.

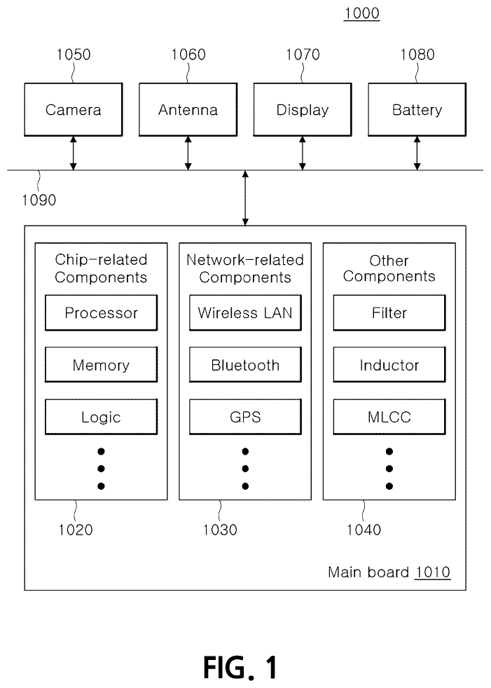

FIG. 1 is a block diagram schematically illustrating an example of an electronic device system.

When referring to the drawing, an electronic device 1000 may accommodate a main board 1010. Various components such as a chip-related component 1020, a network-related component 1030, other components 1040, and the like may be physically and/or electrically connected to the main board 1010. These components may also be coupled to other electronic components described below, thereby forming various signal lines 1090.

The chip-related component 1020 may include one or more of a memory chip such as a volatile memory (e.g., a dynamic random access memory (DRAM)), a nonvolatile memory (e.g., a read only memory (ROM)), or a flash memory; an application processor chip such as a central processor (e.g., CPU), a graphic processor (e.g., a graphics processing unit (GPU)), a digital signal processor, an encryption processor, a microprocessor, or a microcontroller; and a logic chip such as an analog-to-digital converter and an application-specific integrated circuit (ASIC). In addition, the chip-related component 1020 may also include other types of chip-related electronic components.

The network-related component 1030 may include one or more of protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth, 3G, 4G, and 5G protocols, and any other wireless and wired protocols designated after the above-mentioned protocols. In addition, the network-related component 1030 may also include any of various other wireless or wired standards or protocols.

The other components 1040 may include one or more of a high frequency inductor, a ferrite inductor, a power inductor, ferrite beads, low temperature co-firing ceramics (LTCC), an electromagnetic interference (EMI) filter, a multilayer ceramic condenser (MLCC) and the like. In addition, other components 1040 may include various passive components used for other purposes.

The electronic device 1000 may include other electronic components that may be physically and/or electrically connected to the main board 1010, based on a type of the electronic device 1000. Other electronic components may include, for example, a camera module 1050, an antenna module 1060, a display 1070, a battery 1080, and the like. However, the examples are not limited thereto, and may further include an audio codec, a video codec, a power amplifier, a compass, an accelerometer, a gyroscope, a speaker, a mass storage device (e.g., a hard disk drive), a compact disk (CD), a digital versatile disk (DVD), and the like. Furthermore, other electronic components (not shown) may include other electronic components used for various purposes, based on the type of the electronic device 1000.

The electronic device 1000 may be implemented as a smartphone, a personal digital assistant, a digital video camera, a digital still camera, a network system, a computer, a monitor, a tablet, a laptop, a netbook, a television, a video game device, a smart watch, an automotive device, or a server. However, the examples are not limited thereto, and the electronic device may also be implemented as any other device for processing data.

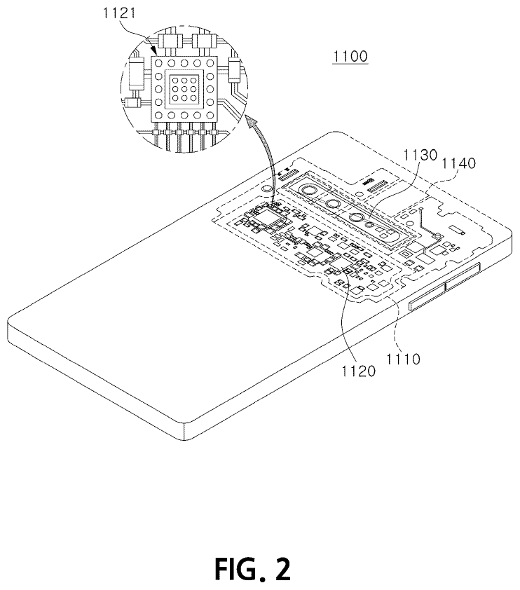

FIG. 2 is a perspective view schematically illustrating an example of the electronic device.

When referring to the drawing, for example, the electronic device 1000 of FIG. 1 may be implemented as a smartphone 1100. The smartphone 1100 may accommodate a motherboard 1110, and various components 1120 may be physically and/or electrically connected to the motherboard 1110. In addition, the smartphone 1100 may accommodate a camera module 1130 (e.g., the camera module 1150 of FIG. 1) and/or a speaker 1140. At least some of the various components 1120 may be included in a component package 1121. The component package 1121 may be implemented as a printed circuit board on which active components and/or passive components are surface-mounted. Alternatively, the component package 1121 may be implemented as a printed circuit board in which active components and/or passive components are embedded. Meanwhile, the electronic device is not necessarily limited to the smartphone 1100 described above and may be implemented as another electronic device as described above.

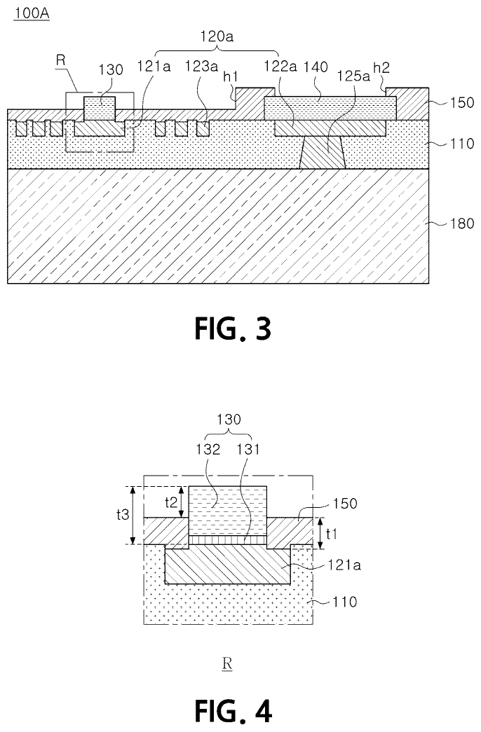

FIG. 3 is a cross-sectional view schematically illustrating a printed circuit board according to an example embodiment.

FIG. 4 is an enlarged cross-sectional view schematically illustrating an R region of the printed circuit board in FIG. 3.

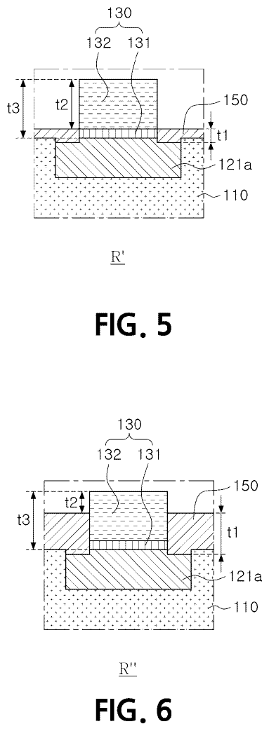

FIG. 5 is an enlarged cross-sectional view schematically illustrating a modified example of the R region in FIG. 4.

FIG. 6 is an enlarged cross-sectional view schematically illustrating another modified example of the R region in FIG. 4.

When referring to the drawings, a printed circuit board 100A according to an example embodiment may include an insulating layer 110, a first conductive pattern 121a embedded in an upper portion of the insulating layer 110 and having an upper surface exposed from an upper surface of the insulating layer 110, a first conductive bump 130 disposed on the first conductive pattern 121a and connected to a first portion of the exposed upper surface of the first conductive pattern 121a, and a solder resist layer 150 disposed on the insulating layer 110, covering a second portion of the exposed upper surface of the first conductive pattern 121a distinct from the first portion of the exposed upper surface of the first conductive pattern 121a (that is, a portion of the exposed upper surface of the first conductive pattern 121a not covered by the first conductive bump 130), covering a first portion of a side surface of the first conductive bump 130, and exposing a second portion of the side surface of the first conductive bump 130 distinct from the first portion of the first conductive bump 130. A plurality of first conductive patterns 121a and a plurality of first conductive bumps 130 may be provided, respectively, and may correspond to a bump structure for mounting of a semiconductor chip (not shown).

As described above, the printed circuit board 100A according to an example embodiment may form the first conductive bump 130 on the first conductive pattern 121a, form the solder resist layer 150 covering these components, and remove the solder resist layer 150 by a specific depth to expose the first conductive bump 130. Therefore, a conventional risk of short circuits may be prevented. Here, a height of the exposed first conductive bump 130 may be directly related to reliability of solder joints obtained by solder bonding. For example, if the exposed height of the first conductive bump 130 is excessively low, solder wettability may be reduced, thus resulting in a weak solder joint structure, and if the exposed height is excessively high, the solder resist layer 150 may become excessively thin, thus causing cracks to occur in the solder resist layer 150.

From this perspective, when a maximum thickness measured from the second portion of the exposed upper surface of the first conductive pattern 121a (that is, the portion of the exposed upper surface of the first conductive pattern 121a not covered by the first conductive bump 130) to an upper surface of the solder resist layer 150 is defined as t1, and a maximum thickness measured from the upper surface of the solder resist layer 150 to an upper surface of the first conductive bump 130 is defined as t2, a thickness ratio of t2 to t1 may be in a range of 7:3 to 2:8. In addition, when a maximum thickness measured from a lower surface of the first conductive bump 130 to the upper surface of the first conductive bump 130 is defined as t3, t1 may be 6 μm to 16 μm, t2 may be 4 μm to 14 μm, and t3 may be 20 μm to 22 μm. When these conditions are satisfied, a risk of short circuits may be prevented, excellent solder wettability may be achieved, and a stable solder resist structure may be simultaneously maintained. For example, optimized conditions for mounting of a semiconductor chip (not shown) may be satisfied.

For example, as shown in the R region in FIG. 4, when t1 and t2 are approximately equal to each other, in a case where a solder ball (not shown) is bonded to the first conductive bump 130, all of the above-described technical effects may be stably ensured. For example, under a condition in which t3 is approximately 20 μm to 22 μm, t1 may be 10 μm to 12 μm, and t2 may be 10 μm to 12 μm. In addition, as shown in an R′ region in FIG. 5, even when t2 is greater than t1, if the above condition is satisfied, in a case where a solder ball (not shown) is bonded to the first conductive bump 130, not only prevention of a risk of short circuits and excellent solder wettability may be achieved, but also a sufficiently stable solder resist structure may be maintained. For example, when t2 is greater than t1, under a condition in which t3 is approximately 20 μm, t1 may be at least 6 μm or more, which may correspond to the minimum condition for preventing cracks from occurring in the solder resist layer. In addition, as shown in an R″ region in FIG. 6, even when t1 is greater than t2, if the above condition is satisfied, in a case where a solder ball (not shown) is bonded to the first conductive bump 130, not only the prevention of a risk of short circuits and a stable solder resist structure may be achieved, but also sufficient solder wettability may be ensured. For example, when t1 is greater than t2, under a condition in which t3 is approximately 20 μm, t2 may be at least 4 μm or more, which may correspond to the minimum condition for avoiding a solder non-wettability risk.

For example, as shown in Table 1 below, when t2:t1 satisfies a range of 7:3 to 2:8, and t1 satisfies a range of 6 μm to 16 μm, t2 satisfies a range of 4 μm to 14 μm, and t3 satisfies a range of 20 μm to 22 μm, for example, in experimental examples 3 to 8, no short circuit may occur, excellent solder wettability may be achieved, and a stable solder resist structure may be maintained. On the other hand, when t2:t1 deviates from 7:3, for example, when t1 is less than 6 μm and t2 is greater than 14 μm, for example, in experimental examples 1 and 2, poor solder wettability may be confirmed. In addition, when t2:t1 deviates from 2:8, for example, when t1 is greater than 16 μm and t2 is less than 4 μm, for example, in experimental example 9, cracks may occur in the solder resist layer 150. Meanwhile, short circuits may be evaluated by an electrical test (e-test), solder wettability may be evaluated by a solder wetting test, and solder resist cracks may be evaluated by a shear test.

TABLE 1

| | | | | | | | Short | Solder | Solder |
|---|---|---|---|---|---|---|---|---|---|
| Classi- | | | | | | | Cir- | Wetta- | Resist |
| fication | t3 | t2 | | t1 | | t2:t1 | cuits | bility | Cracks |
| 1 | 20 μm | 18 | μm | 2 | μm | 1:9 | X | Not good | good |
| 2 | 20 μm | 16 | μm | 4 | μm | 8:2 | X | Not good | good |
| 3 | 20 μm | 14 | μm | 6 | μm | 7:3 | X | good | good |
| 4 | 20 μm | 12 | μm | 8 | μm | 6:4 | X | good | good |
| 5 | 20 μm | 10 | μm | 10 | μm | 5:5 | X | good | good |
| 6 | 20 μm | 8 | μm | 12 | μm | 4:6 | X | good | good |
| 7 | 20 μm | 6 | μm | 14 | μm | 3:7 | X | good | good |
| 8 | 20 μm | 4 | μm | 16 | μm | 2:8 | X | good | good |
| 9 | 20 μm | 2 | μm | 18 | μm | 1:9 | X | good | Not |
| | | | | | | | | | good |

Meanwhile, the second portion of the exposed upper surface of the first conductive pattern 121a (that is, the portion of the exposed upper surface of the first conductive pattern 121a not covered by the first conductive bump 130) may be recessed below the first portion of the exposed upper surface of the first conductive pattern 121a (that is, the portion of the exposed upper surface of the first conductive pattern 121a that is covered by the first conductive bump 130). In addition, the second portion of the exposed upper surface of the first conductive pattern 121a may be recessed below the upper surface of the insulating layer 110. For example, the first conductive pattern 121a may be an embedded trace board (ETS) pattern, and therefore, when a copper foil remaining on a carrier is removed by etching after carrier detachment in an ETS process, a portion of the first conductive pattern 121a may be removed, thus resulting in a recessed step. Here, the copper foil remaining in a region of the upper surface of the first conductive pattern 121a where the first conductive bump 130 is formed may remain as a seed layer of the first conductive bump 130, and thus no recessed step may occur in the corresponding region. Therefore, the above-described result may be obtained. Such a recessed step may be filled with the solder resist layer 150, and thus reliability may be further improved.

Meanwhile, the first conductive bump 130 may include a first metal layer 131 disposed on a portion of the exposed upper surface of the first conductive pattern 121a, and a second metal layer 132 disposed on the first metal layer 131 and having at least a portion protruding above the upper surface of the solder resist layer 150. For example, the first metal layer 131 may include the copper foil of the carrier as described above, and the second metal layer 132 may be formed by electroplating using the first metal layer 131 as a seed layer. For example, the second metal layer 132 may include electrolytic copper. However, the examples are not limited thereto, and the copper foil may be removed from the carrier, and the first metal layer 131 serving as a seed layer may be formed by electroless plating. For example, the first metal layer 131 may include chemical copper. The second metal layer 132 may have a greater thickness than the first metal layer 131.

Meanwhile, the printed circuit board 100A according to an example embodiment may further include a second conductive pattern 122a embedded in the upper portion of the insulating layer 110 to be spaced apart from the first conductive pattern 121a and having an upper surface exposed from the upper surface of the insulating layer 110, a third conductive pattern 123a embedded in the upper portion of the insulating layer 110 to be spaced apart from the first and second conductive patterns 121a and 122a and having an upper surface exposed from the upper surface of the insulating layer 110, and a second conductive bump 140 disposed on the exposed upper surface of the second conductive pattern 122a and partially extending above the upper surface of the insulating layer 110. The solder resist layer 150 may cover a portion of each of the upper and side surfaces of the second conductive bump 140 and may cover the exposed upper surface of the third conductive pattern 123a. The second conductive pattern 122a may have a greater maximum width in cross-section than each of the first and third conductive patterns 121a and 123a. The third conductive pattern 123a may have a smaller minimum width in cross-section than each of the first and second conductive patterns 121a and 122a. A plurality of second conductive patterns 122a and a plurality of second conductive bumps 140 may be provided, respectively, and may correspond to a bump structure used for a substrate-on-substrate application or the like. A plurality of third conductive patterns 123a may be provided and may correspond to a fine circuit structure including patterns for die-to-die connections, escape patterns, or the like.

As described above, the printed circuit board 100A according to an example embodiment may include an interconnection layer 120a including various types of conductive patterns embedded in the upper portion of the insulating layer 110, thus enabling various interconnection designs. For example, the printed circuit board 100A according to an example embodiment may be applied to a structure in which an application processor (AP) (not shown) is packaged in the form of a mold embedded package (MEP), and for example, may be applied to a bottom substrate of the MEP. Here, a plurality of first conductive patterns 121a and a plurality of first conductive bumps 130 respectively connected thereto may be bumps for mounting of a semiconductor chip (not shown), a plurality of second conductive patterns 122a and a plurality of second conductive bumps 140 respectively connected thereto may be bumps for mounting a top substrate on the bottom substrate, and a plurality of third conductive patterns 123a may be interconnection paths designed around the bumps for mounting of a semiconductor chip (not shown), for example, escape patterns. Meanwhile, when a plurality of semiconductor chips (not shown) are mounted on the bottom substrate of the MEP, the plurality of third conductive patterns 123a may also include fine circuit patterns for die-to-die connections.

Meanwhile, the exposed upper surface of the third conductive pattern 123a may be recessed below the upper surface of the insulating layer 110. For example, the third conductive pattern 123a may also be an ETS pattern, and therefore, when a copper foil remaining on a carrier is removed by etching after carrier detachment in an ETS process, a portion of the third conductive pattern 123a may be removed, thus resulting in a recessed step. Such a recessed step may be filled with the solder resist layer 150, and thus reliability may be further improved. On the other hand, the exposed upper surface of the second conductive pattern 122a may be substantially coplanar with the upper surface of the insulating layer 110. For example, the copper foil remaining on the upper surface of the second conductive pattern 122a may remain as a seed layer of the second conductive bump 140, and thus no recessed step may occur in the corresponding region. From this perspective, the second conductive bump 140 may also include a plurality of metal layers, for example, first and second metal layers, similarly to the first conductive bump 130, and the examples are not limited thereto.

Meanwhile, the solder resist layer 150 may include a first opening h1 exposing a portion of each of the upper and side surfaces of the first conductive bump 130 in a region where the first and third conductive patterns 121a and 123a are disposed, and a second opening h2 exposing a portion of the upper surface of the second conductive bump 140 in a region where the second conductive pattern 122a is disposed. When a plurality of first conductive bumps 130 are provided, at least a portion of each of the plurality of first conductive bumps 130 may be exposed through any one first opening h1. When a plurality of second conductive bumps 140 are provided, a plurality of second openings h2 may also be provided to correspond thereto, and each second opening h2 may expose at least a portion of each second conductive bump 140. The region where the first and third conductive patterns 121a and 123a are disposed may be a region where the semiconductor chip (not shown) is mounted. Therefore, a thinning process may be performed in the region of the solder resist layer 150 where the first and third conductive patterns 121a and 123a are disposed, thereby forming the first opening h1. Accordingly, the upper surface of the solder resist layer 150 in the region where the first and third conductive patterns 121a and 123a are disposed may be recessed below the upper surface of the solder resist layer 150 in the region where the second conductive pattern 122a is disposed.

Meanwhile, the printed circuit board 100A according to an example embodiment may further include a board part 180 disposed below the insulating layer 110 and a conductive via 125a penetrating at least a portion of the insulating layer 110 to connect the third conductive pattern 123a to the board part 180. The board part 180 may include at least one insulating layer, at least one interconnection layer, and at least one interconnection via (not individually shown). For example, the board part 180 may include a multilayer substrate structure of a coreless type or a core type. The conductive via 125a may have a smaller width at an upper end than at a lower end in cross-section, which may be a result of the ETS process. A plurality of conductive vias 125a may be provided. In addition to the conductive via 125a, another conductive via (not shown) may also be formed in the insulating layer 110, and the another conductive via may connect at least one of the first conductive pattern 121a or the third conductive pattern 123a to the board part 180.

As described above, the printed circuit board 100A according to an example embodiment may have the multilayer substrate structure of a coreless type or a core type and may be easily used as a package substrate and/or an interposer substrate on which the semiconductor chip (not shown) is mounted. For example, the printed circuit board 100A according to an example embodiment may be applied to a structure in which an AP is packaged in the form of the MEP as described above, may be applied to the bottom substrate of the MEP for example, and the examples are not limited thereto.

Hereinafter, the components included in the printed circuit board 100A according to an example embodiment are described in more detail with reference to the drawings.

The insulating layer 110 may include an insulating material. The insulating material may include a thermosetting resin such as an epoxy resin, a thermoplastic resin such as a polyimide, or a material in which the insulating resin is mixed with an inorganic filler such as silica and/or an organic filler. Alternatively, the insulating material may include a material in which the insulating resin described above is impregnated into a core material such as a glass fiber, glass cloth, or glass fabric together with the inorganic filler and/or the organic filler. For example, the insulating layer 110 may include an insulating material such as a prepreg (PPG), an Ajinomoto build-up film (ABF), a photoimageable dielectric (PID), or a resin coated copper (RCC), and the examples are not limited thereto.

The interconnection layer 120a may include a metal material. For example, the first to third conductive patterns 121a, 122a, and 123a may each include a metal material. The metal material may include copper (Cu), aluminum (Al), silver (Ag), tin (Sn), gold (Au), nickel (Ni), lead (Pb), titanium (Ti), and/or an alloy thereof. For example, the interconnection layer 120a may include electrolytic copper formed by electroplating. For example, the first to third conductive patterns 121a, 122a, and 123a may each include electrolytic copper formed by electroplating. The interconnection layer 120a may perform various functions according to design requirements. For example, the interconnection layer 120a may include a signal transmission pattern, a power transmission pattern, a ground transmission pattern, or the like. For example, the first to third conductive patterns 121a, 122a, and 123a may each include a signal transmission pattern, a power transmission pattern, a ground transmission pattern, or the like. These patterns may have various pattern shapes such as a line, a plane, or a pad. For example, the first and second conductive patterns 121a and 122a may be pad patterns, and the third conductive pattern 123a may be a line pattern.

The first and second conductive bumps 130 and 140 may each include a metal material. The metal material may include copper (Cu), aluminum (Al), silver (Ag), tin (Sn), gold (Au), nickel (Ni), lead (Pb), titanium (Ti), and/or an alloy thereof. For example, the first and second conductive bumps 130 and 140 may each include a copper foil as a seed layer and may include electrolytic copper formed by electroplating on the copper foil as a plating layer. If necessary, the seed layer may include an electroless plated layer, for example, chemical copper. The first and second conductive bumps 130 and 140 may perform various functions according to design requirements. For example, the first and second conductive bumps 130 and 140 may each include a signal transmission bump, a power transmission bump, a ground transmission bump, or the like. The first and second conductive bumps 130 and 140 may each have a circular, elliptical, or polygonal shape in a plane. The first and second conductive bumps 130 and 140 may each have substantially vertical side surfaces in cross-section, and at least a portion of the side surfaces in cross-section may be tapered, if necessary.

The conductive via 125a may include a metal material. The metal material may include copper (Cu), aluminum (Al), silver (Ag), tin (Sn), gold (Au), nickel (Ni), lead (Pb), titanium (Ti), and/or an alloy thereof. For example, the conductive via 125a may include chemical copper formed by electroless plating as a seed layer and may include electrolytic copper formed by electroplating thereon as a plating layer, and the examples are not limited thereto. The conductive via 125a may include a signal transmission via, a power transmission via, a ground transmission via, or the like. The conductive via 125a may have a tapered side surface having a smaller width at an upper end than at a lower end in cross-section. The conductive via 125a may have a filled-plating via structure or may have a conformal-plating via structure.

The solder resist layer 150 may include an insulating material. The insulating material may include a thermosetting resin such as an epoxy resin, a thermoplastic resin such as a polyimide, or an insulating resin including an inorganic filler and/or an organic filler. For example, the solder resist layer 150 may include an Ajinomoto build-up film (ABF) or a solder resist (SR), and the examples are not limited thereto. The solder resist layer 150 may be a liquid type or a film type, and the examples are not limited thereto.

The board part 180 may include at least one insulating layer, at least one interconnection layer, and at least one interconnection via (not individually shown). At least one insulating layer, at least one interconnection layer, and at least one interconnection via may each include a plurality of insulating layers, a plurality of interconnection layers, and a plurality of interconnection vias, respectively. For example, the board part 180 may include a plurality of insulating layers, a plurality of interconnection layers each disposed on or in the plurality of insulating layers, and a plurality of interconnection vias each penetrating at least one of the plurality of insulating layers and connected to at least one of the plurality of interconnection layers.

Each of the plurality of insulating layers may include an insulating material. The insulating material may include a thermosetting resin such as an epoxy resin, a thermoplastic resin such as a polyimide, or a material in which the insulating resin is mixed with an inorganic filler such as silica and/or an organic filler. Alternatively, the insulating material may include a material in which the insulating resin described above is impregnated into a core material such as a glass fiber, glass cloth, or glass fabric together with the inorganic filler and/or the organic filler. For example, each of the plurality of insulating layers may include an insulating material such as a copper clad laminate (CCL), a prepreg (PPG), an Ajinomoto build-up film (ABF), a photoimageable dielectric (PID), or a resin coated copper (RCC), and the examples are not limited thereto. The plurality of insulating layers may be distinguished from one another by interlayer boundaries, but the examples are not limited thereto, and the interlayer boundaries may not be distinguished from one another. For example, at least some of the plurality of insulating layers may include substantially the same insulating material and may also be integrated without boundaries.

Each of the plurality of interconnection layers may include a metal material. The metal material may include copper (Cu), aluminum (Al), silver (Ag), tin (Sn), gold (Au), nickel (Ni), lead (Pb), titanium (Ti), and/or an alloy thereof. For example, each of the plurality of interconnection layers may include chemical copper formed by electroless plating and/or sputtered metal formed by sputtering as a seed layer and may include electrolytic copper formed by electroplating as a plating layer. Each of the plurality of interconnection layers may perform various functions according to design requirements. For example, each of the plurality of interconnection layers may include a signal transmission pattern, a power transmission pattern, a ground transmission pattern, or the like. These patterns may have various pattern shapes such as a line, a plane, or a pad.

Each of the plurality of interconnection vias may include a metal material. The metal material may include copper (Cu), aluminum (Al), silver (Ag), tin (Sn), gold (Au), nickel (Ni), lead (Pb), titanium (Ti), and/or an alloy thereof. For example, each of the plurality of interconnection vias may include chemical copper formed by electroless plating and/or sputtered metal formed by sputtering as a seed layer and may include electrolytic copper formed by electroplating as a plating layer. Each of the plurality of interconnection vias may include a signal transmission via, a power transmission via, a ground transmission via, or the like. Each of the plurality of interconnection vias may have a filled-plating via structure or may have a conformal-plating via structure.

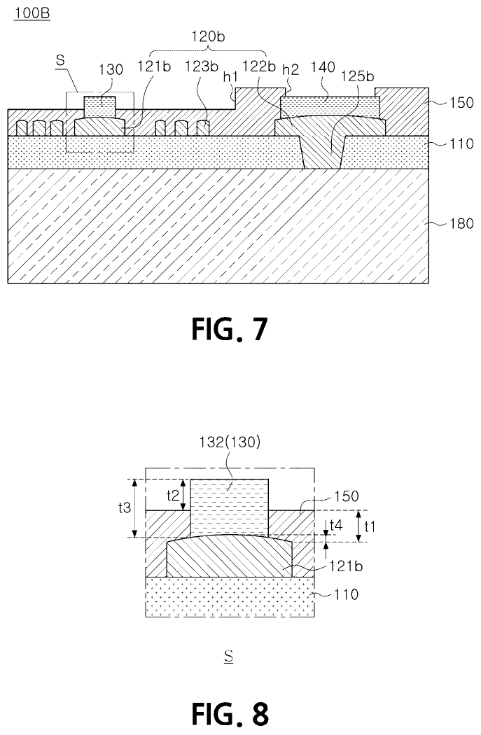

FIG. 7 is a cross-sectional view schematically illustrating a printed circuit board according to another example embodiment.

FIG. 8 is an enlarged cross-sectional view schematically illustrating an S region of the printed circuit board in FIG. 7.

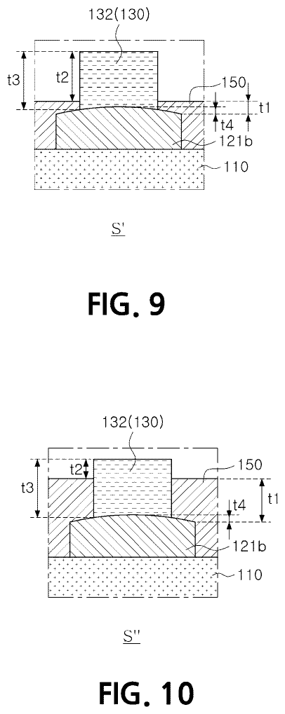

FIG. 9 is an enlarged cross-sectional view schematically illustrating a modified example of the S region in FIG. 8.

FIG. 10 is an enlarged cross-sectional view schematically illustrating another modified example of the S region in FIG. 8.

When referring to the drawings, a printed circuit board 100B according to another example embodiment may include an insulating layer 110, a first conductive pattern 121b disposed on an upper surface of the insulating layer 110 and having a convex upper surface, a first conductive bump 130 disposed on the first conductive pattern 121b and connected to a first portion of the convex upper surface of the first conductive pattern 121b, and a solder resist layer 150 disposed on the insulating layer 110, covering a second portion of the convex upper surface of the first conductive pattern 121b distinct from the first portion of the exposed upper surface of the first conductive pattern 121a (that is, a portion of the exposed upper surface of the first conductive pattern 121b not covered by the first conductive bump 130), covering a first portion of a side surface of the first conductive bump 130, and exposing a second portion of the side surface of the first conductive bump 130 distinct from the first portion of the side surface of the first conductive bump 130. A plurality of first conductive patterns 121b and a plurality of first conductive bumps 130 may be provided, respectively, and may correspond to a bump structure for semiconductor chip mounting.

As described above, the printed circuit board 100B according to another example embodiment may form the first conductive bump 130 on the first conductive pattern 121b, form the solder resist layer 150 covering these components, and remove the solder resist layer 150 by a specific depth to expose the first conductive bump 130. Therefore, the conventional risk of short circuits may be prevented. Here, a height of the exposed first conductive bump 130 may be directly related to reliability of solder joints obtained by solder bonding. For example, if the exposed height of the first conductive bump 130 is excessively low, solder wettability may be reduced, thus resulting in a weak solder joint structure, and if the exposed height is excessively high, the solder resist layer 150 may become excessively thin, thus causing cracks to occur in the solder resist layer 150.

From this perspective, when a maximum thickness measured from the second portion of the convex upper surface of the first conductive pattern 121b to an upper surface of the solder resist layer 150 is defined as t1, and a maximum thickness measured from the upper surface of the solder resist layer 150 to an upper surface of the first conductive bump 130 is defined as t2, a thickness ratio of t2 to t1 may be in the range of 7:3 to 2:8. In addition, when a maximum thickness measured from a lower surface of the first conductive bump 130 to the upper surface of the first conductive bump 130 is defined as t3, t1 may be 6 μm to 16 μm, t2 may be 4 μm to 14 μm, and t3 may be 20 μm to 22 μm. When these conditions are satisfied, a risk of short circuits may be prevented, excellent solder wettability may be achieved, and a stable solder resist structure may be simultaneously maintained. For example, optimized conditions for semiconductor chip mounting may be satisfied.

For example, as shown in the S region in FIG. 8, when t1 and t2 are approximately equal to each other, in a case where a solder ball (not shown) is bonded to the first conductive bump 130, all of the above-described technical effects may be stably ensured. For example, under a condition in which t3 is approximately 20 μm to 22 μm, t1 may be 10 μm to 12 μm, and t2 may be 10 μm to 12 μm. In addition, as shown in an S′ region in FIG. 9, even when t2 is greater than t1, if the above condition is satisfied, in a case where a solder ball (not shown) is bonded to the first conductive bump 130, not only prevention of a risk of short circuits and excellent solder wettability may be achieved, but also a sufficiently stable solder resist structure may be maintained. For example, when t2 is greater than t1, under a condition in which t3 is approximately 20 μm, t1 may be at least 6 μm or more, which may correspond to the minimum condition for preventing cracks from occurring in the solder resist layer. In addition, as shown in an S″ region in FIG. 10, even when t1 is greater than t2, if the above condition is satisfied, in a case where a solder ball (not shown) is bonded to the first conductive bump 130, not only the prevention of a risk of short circuits and a stable solder resist structure may be achieved, but also sufficient solder wettability may be ensured. For example, when t1 is greater than t2, under a condition in which t3 is approximately 20 μm, t2 may be at least 4 μm or more, which may correspond to the minimum condition for avoiding a solder non-wettability risk.

For example, as shown in Table 2 below, when t2:t1 satisfies a range of 7:3 to 2:8, and t1 satisfies a range of 6 μm to 16 μm, t2 satisfies a range of 4 μm to 14 μm, and t3 satisfies a range of 20 μm to 22 μm, for example, in experimental examples 12 to 17, no short circuit may occur, excellent solder wettability may be achieved, and a stable solder resist structure may be maintained. On the other hand, when t2:t1 deviates from 7:3, for example, when t1 is less than 6 μm and t2 is greater than 14 μm, for example, in experimental examples 10 and 11, problems in solder wettability may occur. In addition, when t2:t1 deviates from 2:8, for example, when t1 is greater than 16 μm and t2 is less than 4 μm, for example, in experimental example 18, cracks may occur in the solder resist layer. Meanwhile, short circuits may be evaluated by an electrical test (e-test), solder wettability may be evaluated by a solder wetting test, and solder resist cracks may be evaluated by a shear test.

TABLE 2

| | | | | | | | Short | Solder | Solder |
|---|---|---|---|---|---|---|---|---|---|
| Classi- | | | | | | | Cir- | Wetta- | Resist |
| fication | t3 | t2 | | t1 | | t2:t1 | cuits | bility | Cracks |
| 10 | 20 μm | 18 | μm | 2 | μm | 1:9 | X | Not good | good |
| 11 | 20 μm | 16 | μm | 4 | μm | 8:2 | X | Not good | good |
| 12 | 20 μm | 14 | μm | 6 | μm | 7:3 | X | good | good |
| 13 | 20 μm | 12 | μm | 8 | μm | 6:4 | X | good | good |
| 14 | 20 μm | 10 | μm | 10 | μm | 5:5 | X | good | good |
| 15 | 20 μm | 8 | μm | 12 | μm | 4:6 | X | good | good |
| 16 | 20 μm | 6 | μm | 14 | μm | 3:7 | X | good | good |
| 17 | 20 μm | 4 | μm | 16 | μm | 2:8 | X | good | good |
| 18 | 20 μm | 2 | μm | 18 | μm | 1:9 | X | good | Not |
| | | | | | | | | | good |

Meanwhile, the convex upper surface of the first conductive pattern 121b may have an uppermost point at a central portion and a lowermost point at a peripheral portion connected to a side surface. The convex upper surface of the first conductive pattern 121b may be formed through pattern fill plating using a semi additive process (SAP). The convex upper surface of the first conductive pattern 121b may have a height difference between the lowermost point and the uppermost point, and for example, when the height difference between the lowermost and uppermost points of the first conductive pattern 121b is defined as t4, t4 may be 2 μm to 4 μm. In this case, the thickness of the first conductive bump 130 may be reduced by the above height difference, and a thickness variation of the first conductive bump 130 may be improved. Meanwhile, when t4 is less than 2 μm, the effect may be insignificant, and when t4 is greater than 4 μm, there may be difficulty in bonding of the first conductive pattern 121b with the first conductive bump 130 or in controlling the thickness of the solder resist layer 150.

Meanwhile, the printed circuit board 100B according to another example embodiment may further include a second conductive pattern 122b disposed on the upper surface of the insulating layer 110 to be spaced apart from the first conductive pattern 121b and having a convex upper surface, a third conductive pattern 123b disposed on the upper surface of the insulating layer 110 to be spaced apart from the first and second conductive patterns 121b and 122b and having a convex upper surface, and a second conductive bump 140 disposed on the convex upper surface of the second conductive pattern 122b. The solder resist layer 150 may cover a portion of each of the upper and side surfaces of the second conductive bump 140, may cover a side surface of the second conductive pattern 122b, and may cover the convex upper surface and side surface of the third conductive pattern 123b. The second conductive pattern 122b may have a greater maximum width in cross-section than each of the first and third conductive patterns 121b and 123b. The third conductive pattern 123b may have a smaller minimum width in cross-section than each of the first and second conductive patterns 121b and 122b. A plurality of second conductive patterns 122b and a plurality of second conductive bumps 140 may be provided, respectively, and may correspond to a bump structure used for a substrate-on-substrate application or the like. A plurality of third conductive patterns 123b may be provided and may correspond to a fine circuit structure including patterns for die-to-die connections, escape patterns, or the like.

As described above, the printed circuit board 100B according to another example embodiment may include an interconnection layer 120b including various types of conductive patterns embedded in the insulating layer 110, thus enabling various interconnection designs. For example, the printed circuit board 100B according to another example embodiment may be applied to a structure in which an application processor (AP) (not shown) is packaged in the form of a mold embedded package (MEP), and for example, may be applied to a bottom substrate of the MEP. Here, a plurality of first conductive patterns 121b and a plurality of first conductive bumps 130 respectively connected thereto may be bumps for mounting of a semiconductor chip (not shown), a plurality of second conductive patterns 122b and a plurality of second conductive bumps 140 respectively connected thereto may be bumps for mounting a top substrate on the bottom substrate, and a plurality of third conductive patterns 123b may be interconnection paths designed around the bumps for mounting a semiconductor chip (not shown), for example, escape patterns. Meanwhile, when a plurality of semiconductor chips (not shown) are mounted on the bottom substrate of the MEP, the plurality of third conductive patterns 123b may also include fine circuit patterns for die-to-die connections.

Meanwhile, the convex upper surface of each of the second and third conductive patterns 122b and 123b may have an uppermost point at a central portion and a lowermost point at a peripheral portion connected to a side surface. The convex upper surface of each of the second and third conductive patterns 122b and 123b may be formed through pattern fill plating using an SAP. The convex upper surface of each of the second and third conductive patterns 122b and 123b may have a height difference between the lowermost point and the uppermost point, the height difference may be 2 μm to 4 μm, and the examples are not limited thereto.

Meanwhile, the solder resist layer 150 may include a first opening h1 exposing another portion of each of the upper and side surfaces of the first conductive bump 130 in a region where the first and third conductive patterns 121b and 123b are disposed, and a second opening h2 exposing another portion of the upper surface of the second conductive bump 140 in a region where the second conductive pattern 122b is disposed. When a plurality of first conductive bumps 130 are provided, at least a portion of each of the plurality of first conductive bumps 130 may be exposed through any one first opening h1. When a plurality of second conductive bumps 140 are provided, a plurality of second openings h2 may also be provided to correspond thereto, and each second opening h2 may expose at least a portion of each second conductive bump 140. The region where the first and third conductive patterns 121b and 123b are disposed may be a region where the semiconductor chip (not shown) is mounted, and therefore, a thinning process may be performed in the region of the solder resist layer 150 where the first and third conductive patterns 121b and 123b are disposed, thereby forming the first opening h1. Accordingly, the upper surface of the solder resist layer 150 in the region where the first and third conductive patterns 121b and 123b are disposed may be recessed below the upper surface of the solder resist layer 150 in the region where the second conductive pattern 122b is disposed.

Meanwhile, the printed circuit board 100B according to another example embodiment may further include a board part 180 disposed below the insulating layer 110, and a conductive via 125b penetrating at least a portion of the insulating layer 110 to connect the third conductive pattern 123b to the board part 180. The board part 180 may include at least one insulating layer, at least one interconnection layer, and at least one interconnection via (not individually shown). For example, the board part 180 may include a multilayer substrate structure of a coreless type or a core type. The conductive via 125b may have a greater width at an upper end than at a lower end in cross-section, which may be a result of a build-up process. A plurality of conductive vias 125b may be provided. In addition to the conductive via 125b, another conductive via (not shown) may also be formed in the insulating layer 110, and the another conductive via (not shown) may connect at least one of the first conductive pattern 121b or the third conductive patterns 121b and 123b to the board part 180.

As described above, the printed circuit board 100B according to another example embodiment may have the multilayer substrate structure of a coreless type or a core type and may be easily used as a package substrate and/or an interposer substrate on which the semiconductor chip is mounted. For example, the printed circuit board 100B according to another example embodiment may be applied to a structure in which an AP is packaged in the form of the MEP as described above and may be applied to the bottom substrate of the MEP, and the examples are not limited thereto.

Hereinafter, the components included in the printed circuit board 100B according to another example embodiment are described in more detail with reference to the drawings.

The insulating layer 110 may include an insulating material. The insulating material may include a thermosetting resin such as an epoxy resin, a thermoplastic resin such as a polyimide, or a material in which the insulating resin is mixed with an inorganic filler such as silica and/or an organic filler. Alternatively, the insulating material may include a material in which the insulating resin described above is impregnated into a core material such as a glass fiber, glass cloth, or glass fabric together with the inorganic filler and/or the organic filler. For example, the insulating layer 110 may include an insulating material such as a prepreg (PPG), an Ajinomoto build-up film (ABF), a photoimageable dielectric (PID), or a resin coated copper (RCC), and the examples are not limited thereto.

The interconnection layer 120b may include a metal material. For example, the first to third conductive patterns 121b, 122b, and 123b may each include a metal material. The metal material may include copper (Cu), aluminum (Al), silver (Ag), tin (Sn), gold (Au), nickel (Ni), lead (Pb), titanium (Ti), and/or an alloy thereof. For example, the interconnection layer 120b may include chemical copper formed by electroless plating and electrolytic copper formed by electroplating thereon. For example, the first to third conductive patterns 121b, 122b, and 123b may each include chemical copper formed by electroless plating and electrolytic copper formed by electroplating thereon. The interconnection layer 120b may perform various functions according to design requirements. For example, the interconnection layer 120b may include a signal transmission pattern, a power transmission pattern, a ground transmission pattern, or the like. For example, the first to third conductive patterns 121b, 122b, and 123b may each include a signal transmission pattern, a power transmission pattern, a ground transmission pattern, or the like. These patterns may have various pattern shapes such as a line, a plane, or a pad. For example, the first and second conductive patterns 121b and 122b may be pad patterns, and the third conductive pattern 123b may be a line pattern.

The first and second conductive bumps 130 and 140 may each include a metal material. The metal material may include copper (Cu), aluminum (Al), silver (Ag), tin (Sn), gold (Au), nickel (Ni), lead (Pb), titanium (Ti), and/or an alloy thereof. For example, the first and second conductive bumps 130 and 140 may each include electrolytic copper formed by electroplating as a plating layer. If necessary, an electroless plated layer, for example, chemical copper, may further be included as a seed layer. The first and second conductive bumps 130 and 140 may perform various functions according to design requirements. For example, the first and second conductive bumps 130 and 140 may each include a signal transmission bump, a power transmission bump, a ground transmission bump, or the like. The first and second conductive bumps 130 and 140 may each have a circular, elliptical, or polygonal shape in a plane. The first and second conductive bumps 130 and 140 may each have substantially vertical side surfaces in cross-section, and at least a portion of each of the side surfaces in cross-section may be tapered, if necessary.

The conductive via 125b may include a metal material. The metal material may include copper (Cu), aluminum (Al), silver (Ag), tin (Sn), gold (Au), nickel (Ni), lead (Pb), titanium (Ti), and/or an alloy thereof. For example, the conductive via 125b may include chemical copper formed by electroless plating as a seed layer, may include electrolytic copper formed by electroplating thereon as a plating layer, and the examples are not limited thereto. The conductive via 125b may include a signal transmission via, a power transmission via, a ground transmission via, or the like. The conductive via 125b may have tapered side surfaces having a greater width at an upper end than at a lower end in cross-section. The conductive via 125b may have a filled-plating via structure or may have a conformal-plating via structure.

The solder resist layer 150 may include an insulating material. The insulating material may include a thermosetting resin such as an epoxy resin, a thermoplastic resin such as a polyimide, or an insulating resin including an inorganic filler and/or an organic filler. For example, the solder resist layer 150 may include an Ajinomoto build-up film (ABF) or a solder resist (SR), and the examples are not limited thereto. The solder resist layer 150 may be a liquid type or a film type, and the examples are not limited thereto.

The board part 180 may include at least one insulating layer, at least one interconnection layer, and at least one interconnection via (not individually shown). At least one insulating layer, at least one interconnection layer, and at least one interconnection via may each include a plurality of insulating layers, a plurality of interconnection layers, and a plurality of interconnection vias, respectively. For example, the board part 180 may include a plurality of insulating layers, a plurality of interconnection layers each disposed on or in the plurality of insulating layers, and a plurality of interconnection vias each penetrating at least one of the plurality of insulating layers and connected to at least one of the plurality of interconnection layers.

Each of the plurality of insulating layers may include an insulating material. The insulating material may include a thermosetting resin such as an epoxy resin, a thermoplastic resin such as a polyimide, or a material in which the insulating resin is mixed with an inorganic filler such as silica and/or an organic filler. Alternatively, the insulating material may include a material in which the insulating resin described above is impregnated into a core material such as a glass fiber, glass cloth, or glass fabric together with the inorganic filler and/or the organic filler. For example, each of the plurality of insulating layers may include an insulating material such as a copper clad laminate (CCL), a prepreg (PPG), an Ajinomoto build-up film (ABF), a photoimageable dielectric (PID), or a resin coated copper (RCC), and the examples are not limited thereto. The plurality of insulating layers may be distinguished from one another by interlayer boundaries, the examples are not limited thereto, and the interlayer boundaries may not be distinguished from one another. For example, at least some of the plurality of insulating layers may include substantially the same insulating material and may also be integrated without boundaries.

Each of the plurality of interconnection layers may include a metal material. The metal material may include copper (Cu), aluminum (Al), silver (Ag), tin (Sn), gold (Au), nickel (Ni), lead (Pb), titanium (Ti), and/or an alloy thereof. For example, each of the plurality of interconnection layers may include chemical copper formed by electroless plating and/or sputtered metal formed by sputtering as a seed layer and may include electrolytic copper formed by electroplating as a plating layer. Each of the plurality of interconnection layers may perform various functions according to design requirements. For example, each of the plurality of interconnection layers may include a signal transmission pattern, a power transmission pattern, a ground transmission pattern, or the like. These patterns may have various pattern shapes such as a line, a plane, or a pad.

Each of the plurality of interconnection vias may include a metal material. The metal material may include copper (Cu), aluminum (Al), silver (Ag), tin (Sn), gold (Au), nickel (Ni), lead (Pb), titanium (Ti), and/or an alloy thereof. For example, each of the plurality of interconnection vias may include chemical copper formed by electroless plating and/or sputtered metal formed by sputtering as a seed layer and may include electrolytic copper formed by electroplating as a plating layer. Each of the plurality of interconnection vias may include a signal transmission via, a power transmission via, a ground transmission via, or the like. Each of the plurality of interconnection vias may have a filled-plating via structure or may have a conformal-plating via structure.

In the present disclosure, the expression “cover” a component may include not only a case of entirely covering the component but also a case of covering at least a portion thereof and may include not only a case of directly covering the component but also a case of indirectly covering the component. In addition, the expression “fill” a component may include not only a case of completely filling the component but also a case of filling at least a portion thereof and may further include a case of approximately filling the component. In addition, the expression “surround” a component may include not only a case of completely surrounding the component but also a case of surrounding a portion thereof and a case of approximately surrounding the component. In addition, the expression “expose” a component may include not only a case of completely exposing the component but also a case of exposing a portion thereof, and exposure may refer to a state in which a component is exposed outwardly or a state in which the component is exposed from another component that embeds the corresponding component. For example, that an upper surface of the conductive pattern is exposed from an upper surface of the insulating layer does not necessarily refer to outward exposure, and, for example, another component may further be disposed on the exposed upper surface of the conductive pattern.

In the present disclosure, the expression “substantially” may be determined by including a process error, a positional deviation, a measurement error, and the like that occurs in a manufacturing process. For example, the expression “having a substantially specific shape” may include not only a case of completely having such a shape but also a case of approximately having such a shape. For example, the shape may be determined based on an overall shape. In addition, the expression “substantially the same insulating material” may include not only a case of being completely the same insulating material but also a case of including an insulating material of the same type. Accordingly, compositions of insulating materials may be substantially the same as each other, while specific composition ratios thereof may be slightly different from each other. In addition, the expression “surfaces being substantially coplanar” may include a case in which the surfaces are approximately coplanar with each other.

In the present disclosure, the expression “in cross-section” may refer to a cross-sectional shape of an object when the object is cut vertically, or a cross-sectional shape thereof when the object is viewed in a side view. In addition, the expression “in plan” may refer to a planar shape of an object when the object is cut horizontally, or a planar shape thereof when the object is viewed in a top view or a bottom view.

In the present disclosure, “lower side,” “lower portion,” “lower surface,” and the like are used to refer to a downward direction based on a cross-section of the drawing for convenience of description, and “upper side,” “upper portion,” “upper surface,” and the like are used to refer to an opposite direction. However, these directions are defined for convenience of description, and a scope of the claims is not particularly limited by the descriptions regarding such directions, and concepts of up and down may be changed as appropriate.

In the present disclosure, the expression “connected” refers to a concept including not only a direct connection but also an indirect connection through an adhesive layer or the like. In addition, the expression “electrically connected” refers to a concept including both a physical connection and a physical disconnection. In addition, the expressions such as “first” and “second” are used to distinguish one component from another and do not limit the order, importance, and/or the like of the components. In some cases, without departing from the scope of rights, a first component may be referred to as a second component, and similarly, a second component may be referred to as a first component.

In the present disclosure, thickness, width, length, depth, line width, spacing, pitch, height, and the like may each be measured by a scanning electron microscope or an optical microscope based on a cross-section obtained by polishing or cutting the printed circuit board. A cut cross-section may be a vertical cross-section or a horizontal cross-section, and each numerical value may be measured based on a required cut cross-section. For example, a width of an upper end and/or a lower end of the via may be measured on a cross-section cut along a central axis of the via. When a numerical value is not constant, the numerical value may be determined as an average value of values measured at five arbitrary points. If necessary, a thickness may be used interchangeably with a height.

The expression, “an example embodiment”, used herein does not refer to the same embodiment, and is provided to emphasize each particular feature different from that of another embodiment. However, the example embodiments provided herein do not exclude being implemented in conjunction with the features of another embodiment. For example, one element described in a particular example embodiment may be understood as a description related to another example embodiment even if the example element is not described in another example embodiment, unless an opposite or contradictory description is provided therein.

The terms used herein are used only to describe an example embodiment rather than limit the present disclosure. Here, a term of a singular number includes its plural number unless explicitly interpreted otherwise in context. Here, the term of a singular number includes its plural number unless explicitly interpreted otherwise in the context.

As set forth above, the present disclosure may provide the printed circuit board capable of preventing a risk of short circuits, having excellent solder wettability, and having a stable solder resist structure.

While the example embodiments have been shown and described above, it will be apparent to those skilled in the art that modifications and variations could be made without departing from the scope of the present disclosure as defined by the appended claims.

What is claimed is:

1. A printed circuit board comprising:
an insulating layer;
a first conductive pattern embedded in an upper portion of the insulating layer and having an upper surface exposed from an upper surface of the insulating layer;
a first conductive bump disposed on the first conductive pattern and connected to a first portion of the exposed upper surface of the first conductive pattern; and
a solder resist layer disposed on the insulating layer, covering a second portion of the exposed upper surface of the first conductive pattern distinct from the first portion of the exposed upper surface of the first conductive pattern, covering a portion of a first side surface of the first conductive bump, and exposing a second portion of the side surface of the first conductive bump distinct from the first portion of the first conductive bump,
wherein when a maximum thickness measured from the second portion of the exposed upper surface of the first conductive pattern to an upper surface of the solder resist layer is defined as t1, and a maximum thickness measured from the upper surface of the solder resist layer to an upper surface of the first conductive bump is defined as t2,
a thickness ratio of t2 to t1 is in a range of 7:3 to 2:8.

2. The printed circuit board according to claim 1, wherein when a maximum thickness measured from a lower surface of the first conductive bump to the upper surface of the first conductive bump is defined as t3,
t1 is 6 μm to 16 μm,
t2 is 4 μm to 14 μm, and
t3 is 20 μm to 22 μm.

3. The printed circuit board according to claim 2, wherein t1 is 10 μm to 12 μm, and
t2 is 10 μm to 12 μm.

4. The printed circuit board according to claim 1, wherein the second portion of the exposed upper surface of the first conductive pattern is recessed below at least one of the first portion of the exposed upper surface of the first conductive pattern or the upper surface of the insulating layer.

5. The printed circuit board according to claim 4, wherein the first conductive bump includes
a first metal layer disposed on the first portion of the exposed upper surface of the first conductive pattern, and
a second metal layer disposed on the first metal layer and having at least a portion thereof protruding above the upper surface of the solder resist layer, and
the second metal layer has a greater thickness than the first metal layer.

6. The printed circuit board according to claim 1, further comprising:
a second conductive pattern embedded in the upper portion of the insulating layer to be spaced apart from the first conductive pattern and having an upper surface exposed from the upper surface of the insulating layer;
a third conductive pattern embedded in the upper portion of the insulating layer to be spaced apart from the first and second conductive patterns and having an upper surface exposed from the upper surface of the insulating layer; and
a second conductive bump disposed on the exposed upper surface of the second conductive pattern and partially extending above the upper surface of the insulating layer,
wherein the solder resist layer covers a first portion of each of the upper and side surfaces of the second conductive bump and covers the exposed upper surface of the third conductive pattern,
the second conductive pattern has a greater maximum width in cross-section than each of the first and third conductive patterns, and
the third conductive pattern has a smaller minimum width in cross-section than each of the first and second conductive patterns.

7. The printed circuit board according to claim 6, wherein the solder resist layer includes
a first opening exposing a second portion of each of the upper and side surfaces of the first conductive bump in a region where the first and third conductive patterns are disposed, and
a second opening exposing a second portion of an upper surface of the second conductive bump in a region where the second conductive pattern is disposed, and
the upper surface of the solder resist layer in the region where the first and third conductive patterns are disposed is recessed below the upper surface of the solder resist layer in the region where the second conductive pattern is disposed.

8. The printed circuit board according to claim 6, wherein the exposed upper surface of the second conductive pattern is substantially coplanar with the upper surface of the insulating layer, and
the exposed upper surface of the third conductive pattern is recessed below the upper surface of the insulating layer.

9. The printed circuit board according to claim 6, further comprising:
a board part disposed below the insulating layer; and
a conductive via penetrating at least a portion of the insulating layer to connect the third conductive pattern to the board part,
wherein the board part includes at least one insulating layer, at least one interconnection layer, and at least one interconnection via, and
the conductive via has a smaller width at an upper end than at a lower end in cross-section.

10. A printed circuit board comprising:
an insulating layer;
a first conductive pattern disposed on an upper surface of the insulating layer and having a convex upper surface;
a first conductive bump disposed on the first conductive pattern and connected to a first portion of the convex upper surface of the first conductive pattern; and
a solder resist layer disposed on the insulating layer, covering a second portion of the convex upper surface distinct from the first portion of the convex upper surface, and covering each side surface of the first conductive pattern, covering a first portion of a side surface of the first conductive bump, and exposing a second portion of the side surface of the first conductive bump distinct from the first portion of the first conductive bump,
wherein when a maximum thickness measured from the second portion of the convex upper surface of the first conductive pattern to an upper surface of the solder resist layer is defined as t1, and a maximum thickness measured from the upper surface of the solder resist layer to an upper surface of the first conductive bump is defined as t2,
a thickness ratio of t2 to t1 is in a range of 7:3 to 2:8.

11. The printed circuit board according to claim 10, wherein when a maximum thickness measured from a lower surface of the first conductive bump to the upper surface of the first conductive bump is defined as t3,
t1 is 6 μm to 16 μm,
t2 is 4 μm to 14 μm, and
t3 is 20 μm to 22 μm.

12. The printed circuit board according to claim 11, wherein t1 is 10 μm to 12 μm, and
t2 is 10 μm to 12 μm.

13. The printed circuit board according to claim 10, wherein when a height difference between lowermost and uppermost points of the convex upper surface of the first conductive pattern is defined as t4,
t4 is 2 μm to 4 μm.

14. The printed circuit board according to claim 10, further comprising:
a second conductive pattern disposed on the upper surface of the insulating layer to be spaced apart from the first conductive pattern and having a convex upper surface;
a third conductive pattern disposed on the upper surface of the insulating layer to be spaced apart from the first and second conductive patterns and having a convex upper surface; and
a second conductive bump disposed on the convex upper surface of the second conductive pattern,
wherein the solder resist layer covers a first portion of each of the upper and side surfaces of the second conductive bump and covers the convex upper surface and side surface of the third conductive pattern,
the second conductive pattern has a greater maximum width in cross-section than each of the first and third conductive patterns, and
the third conductive pattern has a smaller minimum width in cross-section than each of the first and second conductive patterns.

15. The printed circuit board according to claim 14, wherein the solder resist layer includes
a first opening exposing a second portion of each of the upper and side surfaces of the first conductive bump in a region where the first and third conductive patterns are disposed, and
a second opening exposing a second portion of an upper surface of the second conductive bump in a region where the second conductive pattern is disposed, and
the upper surface of the solder resist layer in the region where the first and third conductive patterns are disposed is recessed below the upper surface of the solder resist layer in the region where the second conductive pattern is disposed.

16. The printed circuit board according to claim 14, further comprising:
a board part disposed below the insulating layer; and
a conductive via penetrating at least a portion of the insulating layer to connect the third conductive pattern to the board part,
wherein the board part includes at least one insulating layer, at least one interconnection layer, and at least one interconnection via, and
the conductive via has a greater width at an upper end than at a lower end in cross-section.
